(19) United States
(12) Patent Application Publication
(10) Pub. No.: US 2014/0167787 A1
(43) Pub. Date: Jun. 19, 2014

(54) Branch Circuit Current Monitor

(71) Applicant: SCHNEIDER ELECTRIC USA, INC., Palatine, IL (US)

(72) Inventors: Gustavo Garza Sanchez, Nuevo Leon (MX); Efrain Gutierrez, Nuevo Leon (MX); Mauricio Diaz, Nuevo Leon (MX)

(73) Assignee: SCHNEIDER ELECTRIC USA, INC., Palatine, IL (US)

(21) Appl. No.: 13/715,836

(22) Filed: Dec. 14, 2012

(51) Int. Cl. G01R 21/06

(52) U.S. Cl. CPC G01R 21/06
USPC 324/654

(57) ABSTRACT

An electrical system includes a power distribution system having a plurality of branched electrical circuits and current conductors, each of the plurality of branched electrical circuits being coupled to and receiving electrical power from the power distribution system via an associated current conductor of the current conductors. The electrical system also includes a printed circuit board having an array of multiple sensors for monitoring branched power in the plurality of branched electrical circuits. Each individual sensor is in the form of a sensing coil, is mounted to measure electrical power in a respective current conductor of the current conductors, and has its own individual on-board processing circuitry for monitoring the branched power received in the respective current conductor.

### FIELD OF THE INVENTION

This invention is directed generally to electrical systems, and, more particularly, to a board with multiple printed coils for monitoring branched electrical power.

### BACKGROUND OF THE INVENTION

Electrical power in electrical systems is generally supplied from a power source to a power distribution unit and, then, diverted to a plurality of branch circuits. The individual branch circuits provide electrical power to various power loads, such computers, printers, heating devices, lighting devices, etc.

One problem with some present electrical systems is that sensors are not individually installed for each branch circuit connected to the power distribution unit. As such, monitored current levels fail to adequately inform exactly which power loads are causing problems, which branch circuits can handle additional loads, and or which branch circuits are near capacity. Being unable to timely determine, for example, which power load may cause overloading of a conductor cable beyond its nominal current range, can be catastrophic for hospitals, airports, banks, and other industrial facilities that depend heavily on their electric systems to operate smoothly. Heavy human and/or financial losses can result from an electrical failure in these types of environments.

Another problem with some present electrical systems is that they use conventional sensors that are bulky and expensive. For example, such sensors include conventional current transformers and hall effect transducers. The large size of these types of sensors greatly increases costs and/or labor associated with manufacturing and installation.

### SUMMARY OF THE INVENTION

In an implementation of the present invention, a power distribution system distributes electrical power to multiple branch circuits. The power distribution system includes a board with multiple printed coils and individual on-board processing circuitry for each coil to accomplish monitoring branched power to the multiple branch circuits. According to one example, the power distribution system is a load center having an enclosure in which the board is enclosed. Some advantages of the power distribution system include good sensor results with the printed coils, inexpensive manufacturing costs, small components, and compact metering of each branch.

In another implementation of the present invention, an electrical system includes a power distribution system having a plurality of branched electrical circuits and current conductors, each of the plurality of branched electrical circuits being coupled to and receiving electrical power from the power distribution system via an associated current conductor of the current conductors. The electrical system also includes a printed circuit board having an array of multiple sensors for monitoring branched power in the plurality of branched electrical circuits. Each individual sensor is in the form of a sensing coil, is mounted to detect electrical power in a respective current conductor of the current conductors, and has its own individual on-board processing circuitry for monitoring the branched power received in the respective current conductor.

In another alternative implementation of the present invention, an electrical power distribution system includes an electrical distribution enclosure for distributing electrical power to a plurality of branched electrical circuits including a first circuit branch and a second circuit branch. A first current conductor is electrically connecting the first circuit branch to the electrical distribution enclosure, and a second current conductor is electrically connecting the second circuit branch to the electrical distribution enclosure. A printed circuit board is electrically and mechanically connected to the electrical distribution enclosure and has multiple sensors for monitoring electrical power in the plurality of branched electrical circuits. The multiple sensors include a first sensor in the form of a first sensing coil located proximate a first aperture on the printed circuit board, the first current conductor being inserted through the first aperture. The multiple sensors also include a second sensor in the form of a second sensing coil located proximate a second aperture on the printed circuit board, the second current conductor being inserted through the second aperture. The electrical power distribution system further includes individual on-board processing circuitry mounted on the printed circuit board. The processing circuitry includes first circuitry proximate the first sensor for monitoring branched power in the first circuit branch, and second circuitry proximate the second sensor for monitoring branched power in the second circuit branch.

Additional aspects of the invention will be apparent to those of ordinary skill in the art in view of the detailed description of various embodiments, which is made with reference to the drawings, a brief description of which is provided below.

### BRIEF DESCRIPTION OF THE DRAWINGS

The invention may best be understood by reference to the following description taken in conjunction with the accompanying drawings.

FIG. 1 is an illustration of an electrical system with branched electrical power.

FIG. 2 is a perspective view illustrating an enclosure with a printed circuit board having multiple sensors.

FIG. 3 is a front enlarged view of the printed circuit board of FIG. 2.

FIG. 4 is a front enlarged view of a single sensor of the multiple sensors of FIG. 2.

FIG. 5 is a front view of a printed circuit board being split into two board sections.

### DETAILED DESCRIPTION OF THE ILLUSTRATED EMBODIMENTS

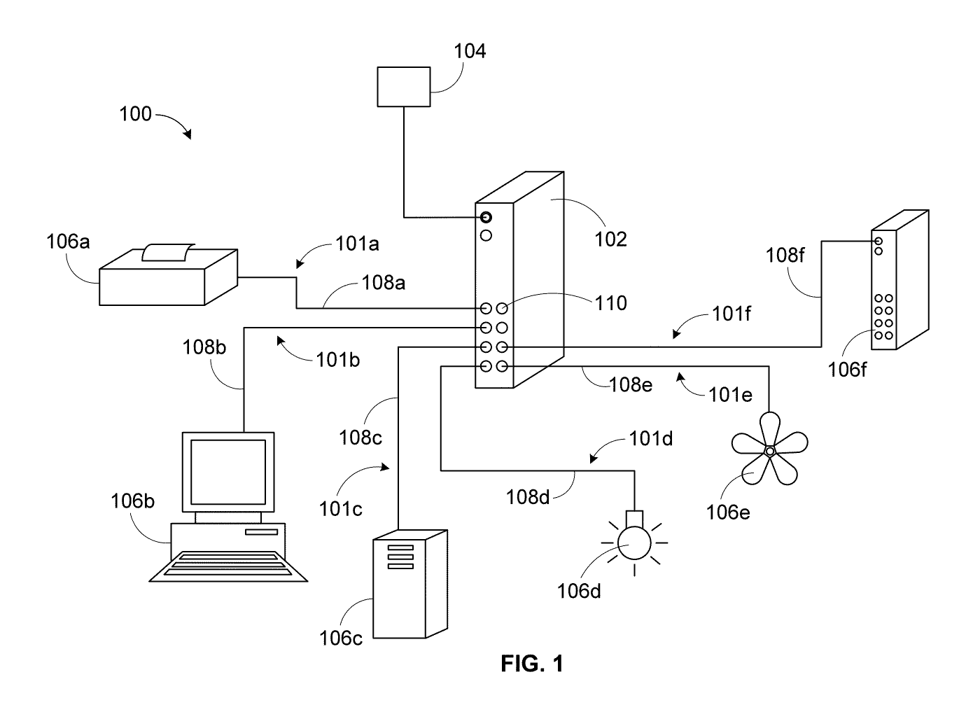

Referring to FIG. 1, an electrical system 100 represents an energy management system or a smart grid having a plurality of branched circuits 101a-101f. Generally, the electrical system 100 provides individual current sensing for measuring circuit current in each of the branched circuits 101a-101f. Specifically, the electrical system 100 includes a power distribution system 102 that receives electrical power from a power source 104 and is communicatively coupled to the branched circuits 101a-101f for transmitting electrical power to a plurality of electrical loads 106a-106f. The power distribution system 102 can include, for example, a panelboard, a loadcenter, a meter, a switchboard, a switchgear, etc. The electrical loads 106a-106f include, for example, a printer 106a, a computer 106b, a server 106c, a lighting system 106d, an air-conditioning system 106e, and a power sub-distribution system 106f. The power sub-distribution system 106f can be coupled, in turn, to other electrical loads and can function similar (if not identical) to the power distribution system 102.

Each branched-circuit communication between the power distribution system 102 and the electrical loads 106a-106f is achieved via current conductors 108a-108f of respective branched circuits 101a-101f. While the branched circuits 101a-101f generally refer to the electrical path between the power distribution system 102 and the respective electrical loads 106a-106f, the current conductors 108a-108f refer more specifically to the material that allows the electrical current to flow through the respective circuits. For example, the current conductors can be in the form of wires made of conductive materials for allowing electrical current to flow through respective circuits of the branched circuits 101a-101f. Alternatively, the current conductors 108a-108f can be in the form of cables, flat laminations, or extrusions.

To accurately monitor power consumption in the electrical system 100, the power distribution 102 includes a plurality of individual sensors 110 that measure branched electrical power transmitted through the current conductors 108a-108f of the branched circuits 101a-101f. As described in more detail below, the sensors 110 provide independent current sensing capacity for the branched circuits 101a-101f.

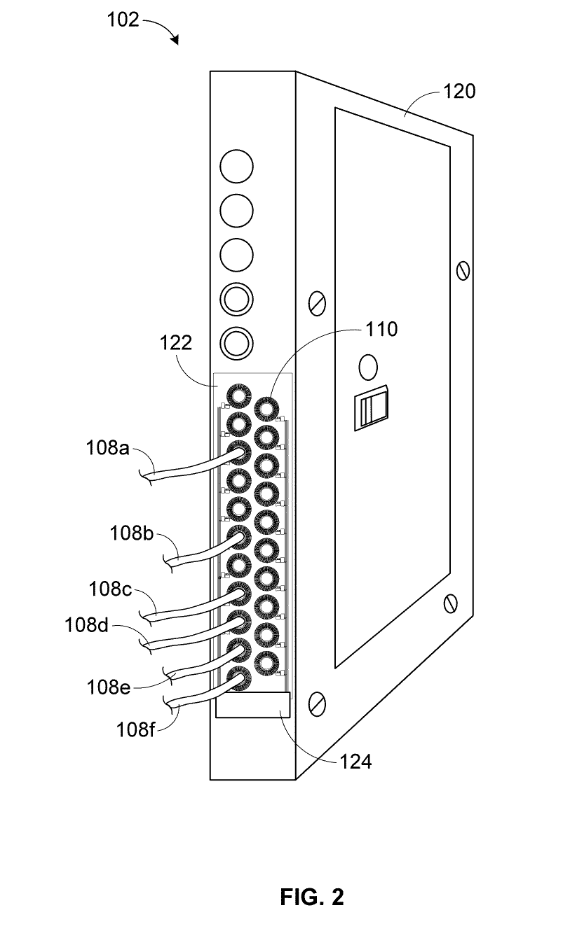

Referring to FIG. 2, the power distribution system 102 includes a branched circuit distribution enclosure 120 for facilitating connections to the electrical loads 106a-106f and for housing internal energy management components, e.g., circuit breakers. The current conductors 108a-108f are electrically and mechanically connected to the enclosure 120, passing through respective sensors 110 into the enclosure 120.

The enclosure 120 includes a printed circuit board 122 that is mounted at an exterior side panel of the enclosure 120. Alternatively, the board 122 is mounted within the enclosure 120 or is attached to an exterior surface of the enclosure 120. The board 122 is coupled to a receiving terminal 124 of the enclosure 120. An exemplary thickness for the board 122 can range from approximately 1.6 millimeters to approximately 5 millimeters. In another alternative implementation, the printed circuit board 122 is mounted as the side panel of the enclosure 120.

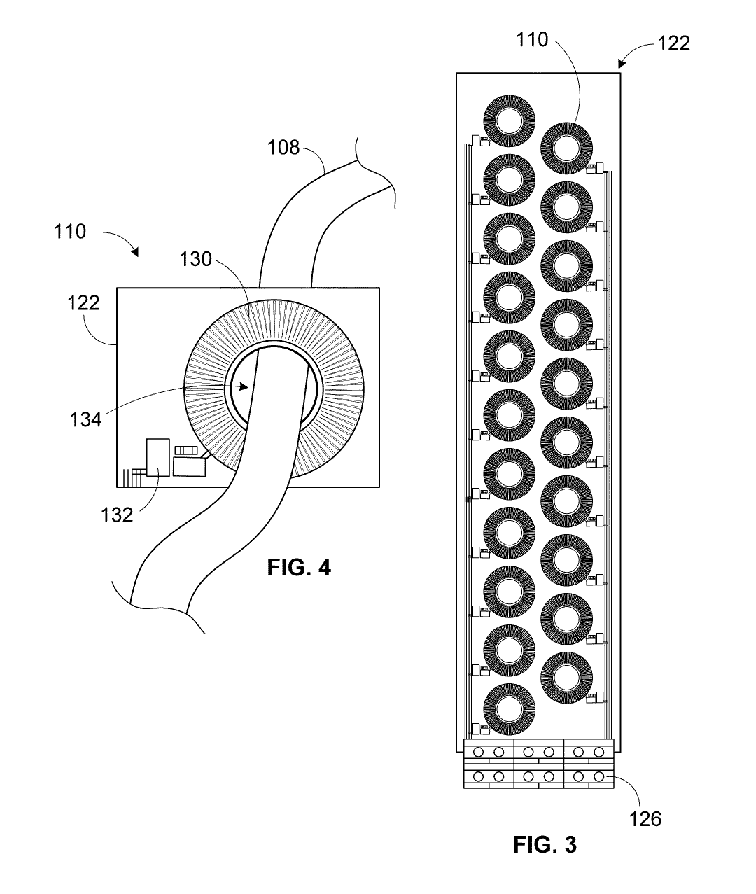

Referring to FIG. 3, the sensors 110 are arranged on the board 122 in the form of an array having two columns and multiple rows. In other embodiments, the array of sensors 110 can include circular and/or rectangular patterns as required to facilitate current sensing needs. In addition, the number of sensors 110 can be in excess of initial needs to allow future expansion of the power distribution system 102 to other electrical loads (e.g., heating systems, electrical tools, additional servers, etc.).

The board 122 includes at a bottom end a connector terminal 126. When the board 122 is mounted in position on the enclosure 120, the connector terminal 126 is inserted into the receiving terminal 124 of the enclosure 120. Because the board 122 includes only one connector terminal 126, mounting of the board 122 to the enclosure 120 is achieved with ease and simplicity. An installer has to make a single connection in which the interface only requires insertion of one component (i.e., the connector terminal 126) into another component (i.e., the receiving terminal 124). As such, the board 122 does not require multiple connections and/or special tools (if any).

Referring to FIG. 4, a sensor 110 from the array of sensors on board 122 includes a sensing coil 130 and processing circuitry 132 for measuring electrical current and/or energy. The sensor 110 can sense current in any amperage range, e.g., from a few Amperes in loadcenters to thousands of Amperes in panelboards. The coil 130 can be a Rogowski coil, which consists of a helical coil of wire with a lead from one end returning through the center of the coil to the other end so that both terminals are at the same end of the coil. The coil 130 is wrapped on the board 122 around an aperture (or eyelet) 134 through which a current conductor 108 is inserted.

The sensor 110 provides sensing technology that is capable of being miniaturized and easily industrialized. Accordingly, some advantages of the sensor 110 include isolated measurement of electrical current, high manufacturing reproducibility, and low manufacturing cost. For example, printed coil can provide manufacturing savings by a factor of ten in contrast to iron core sensors (e.g., approximately $50 for 40 coil sensors vs. approximately $500 for 40 iron core sensors). In another example, the small size of the sensor 110 allows compact metering of each branch 101a-101f and, therefore, enabling smart metering (e.g., where apartments are on branch circuits). As such, lower bulk of the metering system results in a lower metering expense.

Another advantage of the sensor 110 stems from the lack of ferromagnetic material. Because the coil 130 does not contain iron, small electronic components can be mounted on the board 122 right next to the coil 130 for each sensor 110. Small electronic components are typically required for sensing a small current signal. Typical iron core sensors, which are extremely bulky, would require large electronic components that would be mounted far from the measured current conductor. In contrast to the iron core sensors, the sensor 110 includes small sensing electronics right next to the coil 130 for measuring small current signals. Furthermore, the coil 130 has low power loss, which, in turn, means that low heat is generated. As such, low heat further helps in having small sensing electronics closer to the coil 130 because cooling the electronics does not cause a problem.

Based on the inherent electronic nature of the sensor 110, yet another advantage of the sensor 110 is that it can be easily calibrated. For example, an electronics device adjustment, such as a potentiometer, can be used to calibrate the sensor 110.

The processing circuitry 132 provides individual on-board processing circuitry for monitoring the branched power received in the current conductor 108. The processing circuitry 132 includes, for example, all data processing—including conditioning and electronics to accomplish monitoring the branched power. Accordingly, the processing circuitry 132 processes an output signal received from the coil 130 and provides a measured current or energy parameter (e.g., a current value).

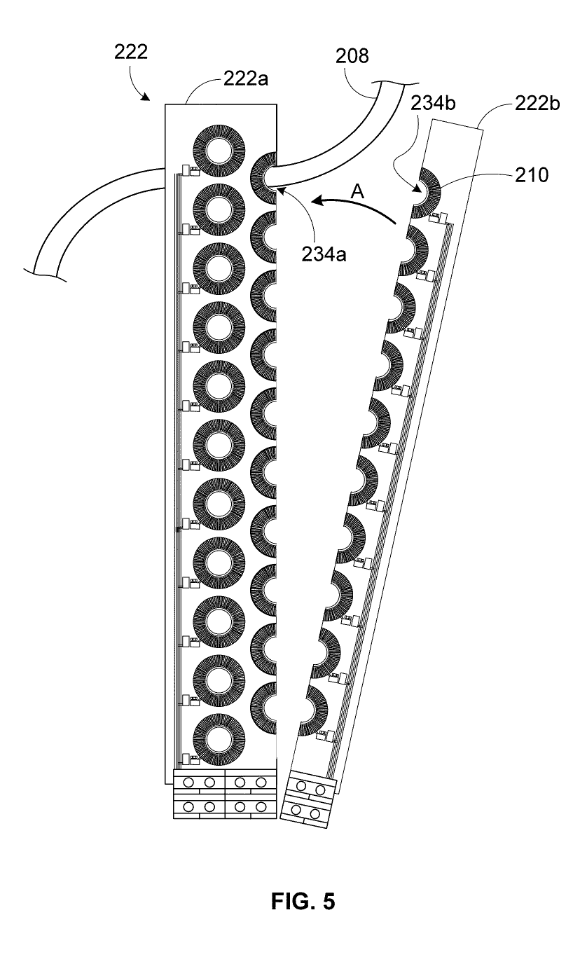

Referring to FIG. 5, an alternative embodiment includes a printed circuit board 222 that has sensors split into two symmetrical sections for allowing conductor allocation. The board 222 is optionally a single board that is split into a first section 222a and a second section 222b. To allocate a conductor 208 such that it passes through a respective sensor 210, the two sections 222a, 222b are initially separated. After locating the conductor 208 within a first partial aperture 234a, the second section 222b is moved in contact with the first section 222a (as illustrated by arrow A) to make complete the sensor 210. The complete sensor 210 has the first partial aperture 234a form a complete internal aperture with a second partial aperture 234b. The split board 222 is beneficial for easy installation in new systems or for retrofitting old systems.

While particular embodiments, aspects, and applications of the present invention have been illustrated and described, it is to be understood that the invention is not limited to the precise construction and compositions disclosed herein and that various modifications, changes, and variations may be apparent from the foregoing descriptions without departing from the spirit and scope of the invention as defined in the appended claims. For example, the sensor can have an elliptical or oval shape that provides increased turn density for the coil and good sensing accuracy. In another example, the board and/or the sensor have modular interfaces to customize branch power sensing in accordance with changing needs.

What is claimed is:

1. An electrical system comprising:
a power distribution system having a plurality of branched electrical circuits and current conductors, each of the plurality of branched electrical circuits being coupled to and receiving electrical power from the power distribution system via an associated current conductor of the current conductors; and
a printed circuit board having an array of multiple sensors for monitoring branched power in the plurality of branched electrical circuits, each individual sensor of the array of multiple sensors
(a) being in the form of a sensing coil,
(b) being positioned to measure electrical power in a respective current conductor of the current conductors, and
(c) having its own individual on-board processing circuitry for monitoring the branched power received in the respective current conductor.

2. The electrical system of claim 1, further comprising a branched circuit distribution enclosure, the current conductors being electrically and mechanically connected to the branched circuit distribution enclosure.

3. The electrical system of claim 2, wherein the printed circuit board is electrically and mechanically coupled to the branched circuit distribution enclosure.

4. The electrical system of claim 3, wherein the printed circuit board includes a connector terminal, the connector terminal being electrically and mechanically connected to the branched circuit distribution enclosure.

5. The electrical system of claim 2, wherein the printed circuit board is mounted at a side panel of the branched circuit distribution enclosure.

6. The electrical system of claim 1, wherein each individual sensor measures electrical current of the associated current conductor.

7. The electrical system of claim 1, wherein each individual sensor measures energy of the associated current conductor.

8. The electrical system of claim 1, wherein the printed circuit board is in unitary form and includes apertures for each of the multiple sensors, the current conductors being inserted, respectively, through the apertures.

9. The electrical system of claim 1, wherein the printed circuit board includes apertures for each of the multiple sensors, the printed circuit board being split into at least two board sections to accommodate insertion of each sensor within a respective aperture.

10. The electrical system of claim 1, wherein each sensor of the array of multiple sensors includes an aperture, through which the respective current conductor is inserted, having a shape selected from a group consisting of a circular shape, an oval shape, and a rectangular shape.

11. The electrical system of claim 1, wherein the array of multiple sensors is a matrix having at least two rows and two columns of sensors.

12. An electrical power distribution system comprising:
an electrical distribution enclosure for distributing electrical power to a plurality of branched electrical circuits including a first circuit branch and a second circuit branch;
a first current conductor electrically connecting the first circuit branch to the electrical distribution enclosure;
a second current conductor electrically connecting the second circuit branch to the electrical distribution enclosure;
a printed circuit board electrically and mechanically connected to the electrical distribution enclosure, the printed circuit board having multiple sensors for monitoring electrical power in the plurality of branched electrical circuits, the multiple sensors including
a first sensor in the form of a first sensing coil located proximate a first aperture on the printed circuit board, the first current conductor being inserted through the first aperture,
a second sensor in the form of a second sensing coil located proximate a second aperture on the printed circuit board, the second current conductor being inserted through the second aperture; and
individual on-board processing circuitry mounted on the printed circuit board and including first circuitry and second circuitry, the first circuitry being proximate the first sensor for monitoring branched power in the first circuit branch, the second circuitry being proximate the second sensor for monitoring branched power in the second circuit branch.

13. The electrical power distribution system of claim 12, wherein the printed circuit board includes a connector terminal via which the printed circuit board is electrically and mechanically connected to the electrical distribution enclosure.

14. The electrical power distribution system of claim 12, wherein the printed circuit board is located within the electrical distribution enclosure.

15. The electrical power distribution system of claim 12, wherein the printed circuit board is mounted at a side panel of the electrical distribution enclosure.

16. The electrical power distribution system of claim 12, wherein the electrical distribution enclosure encloses one or more of a panelboard, a load center, and a metering system.

17. The electrical power distribution system of claim 12, wherein the printed circuit board is split into at least two board sections to accommodate insertion of the first sensor and the second sensor within the first aperture and the second aperture, respectively.

18. The electrical power distribution system of claim 12, the first aperture and the second aperture have shapes selected from a group consisting of a circular shape, an oval shape, and a rectangular shape.

19. The electrical power distribution system of claim 12, wherein the multiple sensors are arranged in the form of a matrix having at least two rows and two columns of sensors.
